(19) United States
(12) Patent Application Publication
(10) Pub. No.: US 2025/0055102 A1
(43) Pub. Date: Feb. 13, 2025

(54) SMART PACKAGING AND INVENTORY CONTROL FOR BATTERIES CONFIGURED FOR USE WITH ENERGY MANAGEMENT SYSTEMS

(71) Applicant: Enphase Energy, Inc., Petaluma, CA (US)

(72) Inventors: Jonathan List EHLMANN, Austin, TX (US); Conner O’Grady FEAR, Glen Ellen, CA (US); Chien-Fan CHEN, Fremont, CA (US)

(21) Appl. No.: 18/791,019

(22) Filed: Jul. 31, 2024

Related U.S. Application Data
(60) Provisional application No. 63/531,464, filed on Aug. 8, 2023.

(51) Int. Cl. H01M 50/202; G01R 31/36; G01R 31/382; G01R 31/392; G01R 31/396; H01M 10/42; H01M 10/48; H01M 10/613; H01M 10/635; H01M 10/6572; H01M 50/238; H01M 50/271

(52) U.S. Cl. CPC H01M 50/202; G01R 31/3646; G01R 31/382; G01R 31/392; G01R 31/396; H01M 10/486; H01M 10/613; H01M 10/635; H01M 10/6572; H01M 50/238; H01M 50/271; H01M 2010/4271

(57) ABSTRACT

An apparatus for smart packaging and inventory control is provided herein and comprises a housing comprising a lid configured to be opened and closed to allow a battery to be loaded and unloaded to and from the housing and a controller configured to monitor at least one of a battery state of health or a battery state of charge when the battery is disposed in the housing and display the state of health or the state of charge of the battery via an indicator on the housing.

### CROSS-REFERENCE TO RELATED APPLICATIONS

The present application claims the benefit of and priority to U.S. Provisional Application Ser. No. 63/531,464, filed on Aug. 8, 2023, the entire contents of which is incorporated herein by reference.

### BACKGROUND

### 1. Field of the Disclosure

Embodiments of the present disclosure generally relate to smart packaging and inventory control for batteries configured for use with energy management systems.

### 2. Description of the Related Art

Energy management systems can comprise one or more batteries. During a storage period prior to installation of a battery, battery performance and safety may gradually decrease, and the impact of storage time on performance can be highly dependent on storage conditions. For example, storing a battery at elevated temperatures is known to cause accelerated degradation, so even if a manufacturer is able to sell the batteries, there is a chance that the batteries may not meet original warranty expectations. Furthermore, poor inventory management can cause batteries to exceed expiration dates before the batteries can be installed, resulting in a manufacturer's lost revenue.

Therefore, described herein are improved methods and apparatus for smart packaging and inventory control for batteries configured for use with energy management systems.

### SUMMARY

In accordance with some aspects of the present disclosure, an apparatus for smart packaging and inventory control comprises a housing comprising a lid configured to be opened and closed to allow a battery to be loaded and unloaded to and from the housing and a controller configured to monitor at least one of a battery state of health or a battery state of charge when the battery is disposed in the housing and display the state of health or the state of charge of the battery via an indicator on the housing.

Various advantages, aspects, and novel features of the present disclosure may be appreciated from a review of the following detailed description of the present disclosure, along with the accompanying figures in which like reference numerals refer to like parts throughout.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only a typical embodiment of this disclosure and are therefore not to be considered limiting of its scope, for the disclosure may admit to other equally effective embodiments.

FIG. 1 is a diagram of a smart packaging apparatus with a battery disposed therein, in accordance with at least some embodiments of the present disclosure; and

FIG. 2 is a diagram of a display configured for use with the smart packaging apparatus of FIG. 1, in accordance with at least some embodiments of the present disclosure.

### DETAILED DESCRIPTION

In accordance with the present disclosure, described herein are improved methods and apparatus for smart packaging and inventory control for batteries configured for use with energy management systems, such as the energy management system described in commonly-owned U.S. patent application Ser. No. 17/716,059, the entire contents of which is incorporated herein by reference. For example, an apparatus for smart packaging and inventory control can comprise a housing comprising a lid configured to be opened and closed to allow a battery to be loaded and unloaded to and from the housing. A controller is configured to monitor at least one of a battery state of health or a battery state of charge when the battery is disposed in the housing and display the state of health or the state of charge of the battery via an indicator on the housing. The methods and apparatus described herein can track storage conditions of a battery and help extend the battery storage life and ensure that the battery is safe to use and able to meet warranty expectations after installation. Furthermore, the methods and apparatus described herein provide improved inventory management and tracking to facilitate first in first out processes at distribution and installer network.

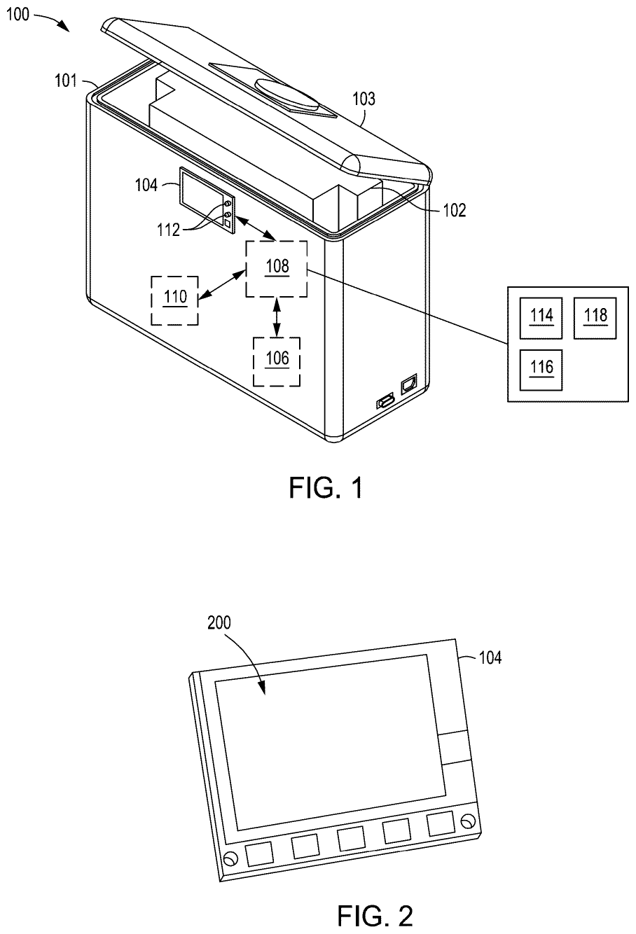

FIG. 1 is a diagram of a smart packaging apparatus 100 with a battery 102 disposed therein, in accordance with at least some embodiments of the present disclosure. For example, the smart packaging apparatus 100 comprises a housing 101 and a lid 103 that can be opened and closed with respect to the housing 101, which allows a user to load and unload the battery 102 into and from the housing 101. In at least some embodiments, the lid 103 can be connected to the housing 101 via one or more hinges (not shown). The housing 101 comprises one or more indicators 104 to display messages and/or attract attention to defective units (e.g., batteries). In at least some embodiments, the one or more indicators 104 can comprise one or more LED and/or E-INK indicators that can display information about the battery 102 and/or the smart packaging apparatus 100. In at least some embodiments, the one or more LED and/or E-INK indicators can blink to aid in finding the smart packaging apparatus 100, e.g., when the unit is inside a warehouse. In at least some embodiments, the smart packaging apparatus 100 can comprise one or more auxiliary power supplies. In at least some embodiments, the smart packaging apparatus 100 can comprise an accelerometer 110 that is configured to detect, for example, abuse, drops, and/or report damage, which can provide protective measures against accidental drops or rough handling during shipping, which can make the battery 102 unsafe to use. The smart packaging apparatus 100 can be configured to identify and/or display damage and end of life status of the battery 102, e.g., via the one or more indicators 104. In at least some embodiments, one or more buttons 112 can be provided on the one or more indicators 104. For example, the one or more buttons 112 can be used for reporting data via low power wireless communication, such as BLE or LoRa.

The smart packaging apparatus 100 is a temperature-controlled enclosure to protect the battery 102 and prolong the battery 102 storage life. For example, the smart packaging apparatus 100 is thermally insulated, and a storage temperature can be maintained at an optimal level (e.g., <25° C.) using, for example, a Peltier cooler that can be connected to one or more sensors 106. In at least some embodiments, the one or more sensors can comprise one or more temperature sensors that are configured to sense the temperature of the battery and/or an interior of the smart packaging apparatus 100. Accordingly, in at least some embodiments, the smart packaging apparatus 100 can be configured as a safe enclosure for thermal runaway to occur, so the smart packaging apparatus 100 can be used to transport both new and damaged battery packs. As such, the smart packaging apparatus 100 can comprise one or more pressure release valves (not shown) for safe venting of gases generated during thermal runaway.

A controller 108 is configured to track SOH (state-of-health) of the battery through a predictive model. In at least some embodiments, the controller 108 can be configured to communicate the SOH over wired communication (or wireless communication). In such embodiments, the controller 108 can be connected to the one or more auxiliary power supplies to provide power for communicating the SOH. The controller 108 comprises support circuits 114 and a memory 116, each coupled to a CPU 118 (central processing unit). The CPU 118 may comprise one or more conventionally available microprocessors or microcontrollers. Alternatively, the CPU 118 may include one or more application specific integrated circuits (ASICs). The controller 108 may be implemented using a general purpose computer that, when executing particular software, becomes a specific purpose computer for performing various embodiments of the present disclosure. In one or more embodiments, the CPU 118 may be a microcontroller comprising internal memory for storing controller firmware that, when executed, provides the controller functionality described herein. The support circuits 144 are well known circuits used to promote functionality of the CPU 118. Such circuits include, but are not limited to, a cache, power supplies, clock circuits, buses, input/output (I/O) circuits, and the like. The memory 116 may comprise random access memory, read only memory, removable disk memory, flash memory, and various combinations of these types of memory. The memory 116 is sometimes referred to as main memory and may, in part, be used as cache memory or buffer memory. The memory 116 generally stores an OS (operating system), if necessary, of the controller 108 that can be supported by the CPU capabilities. In some embodiments, the OS may be one of a number of commercially available operating systems such as, but not limited to, LINUX, Real-Time Operating System (RTOS), and the like. The memory 116 stores various forms of application software when executed, implementing the techniques described herein. The memory 116 additionally stores a database, for example for storing data (e.g., a predictive model) related to the operation of the smart packaging apparatus 100.

The methods and apparatus described herein provide mapping of a battery's shipping and storage conditions from manufacture to deployment. For example, the inventors have developed an apparatus (e.g., a hardware device) to track storage temperature over time without draining energy from the battery. Based on the storage temperature profile the apparatus records, the apparatus uses a predictive model to determine the impact of storage on battery SOH. The predictive model combines an exponential decay function with an Arrhenius function to estimate a capacity loss as a function of time and temperature. The battery SOH can be calculated as the ratio of retained capacity of the battery to an original capacity of the battery using Equations (1-3). For example, Equation (1) represents a capacity loss at time step t and temperature T, Equation (2) represents a capacity retention update, and Equation (3) represents a SOH update.

$${Q}_{loss} ( T , t ) = A * exp ( - B * t ) \times ( exp ( - {E}_{a} / {R}_{g} ( \frac{1}{T} - \frac{1}{25 + 273} ) ) \qquad ( 1 )$$

$${Cap}_{retention} ( t ) = {Cap}_{retention} ( t - 1 ) - {Q}_{loss} ( T , t ) \qquad ( 2 )$$

$$SOH ( t ) = \frac{{Cap}_{retention} ( t )}{{Cap}_{initial}} \qquad ( 3 )$$

The parameters A, B, E, and R can be obtained using one or more curve fitting of experimental data (e.g., long-term storage test data at different temperatures with periodic charge/discharge to assess remaining capacity). Once the SOH has been calculated, the SOH of the battery can be displayed on, for example, a visual indicator 200 and/or can be wirelessly communicated (or via wired communication) to a central database or computing device (see FIG. 2). The SOH can be used to adjust a warranty and/or sale prices for one or more batteries. To communicate the SOH recorded by the apparatus, one or more software tools/applications can be used to track and trace the batteries.

Additionally, batteries sometimes have to be removed from conventional packaging containers and recharged (e.g., about every 3-6 months) to ensure that the batteries are not over discharged due to self-drain. Currently, there is no way, however, to track if the batteries have been recharged, and the inventors have found that batteries sometimes exit the packaging container at the installation site with 0% SOC and must be returned to the manufacturer so that the batteries can be recharged. For example, generally, the batteries can be recharged at a distribution center, installer warehouse, or installation site as long as SOC is >0% (e.g., V_{cell}>2.5 V), although optimal storage conditions are 20%<SOC<30%. But if a self-drain is severe enough to bring it below 0% (e.g., V_{cell}<2.5 V), then the battery must be recycled, as it is unsafe to recharge. Accordingly, the smart packaging apparatus 100 is configured for active monitoring of battery state of charge (SOC) and for easy recharging. For example, the smart packaging apparatus 100 is configured for monitoring and recharging of the battery by connecting the battery to the smart packaging apparatus 100 with a 24 V power supply and control area network (CAN) connection (e.g., a CAN bus) to turn on a battery management unit (BMU), which is connected to the battery, periodically and read the SOC of the battery. Thus, if the SOC falls outside of an acceptable range (e.g., about 20%-30%), under control of the controller 108, the one or more indicators 104 can display an early warning that recharging is needed. Thereafter, the CAN+24V connection can provide periodic battery recharging in a relatively simple manner, as the battery does not need to be removed from the smart packaging apparatus 100 to maintain an adequate SOC of the battery.

The smart packaging apparatus 100 can be used with both new and old batteries. For example, with respect to new batteries, smart packaging apparatus 100 is configured to ensure a first in first out supply chain management. The smart packaging apparatus 100 can be configured to automatically report SOH and SOC daily and report any errors immediately. Similarly, for old batteries, the smart packaging apparatus 100 provides for safe shipping of defective or end of life batteries, and for reusable packaging which can reduce the environmental impact and shipping risk. In at least some embodiments, the housing 101 can be collapsible/foldable so that empty smart packaging apparatus 100 can be efficiently stored and transported back and forth to/from a factory. In such embodiments, one or more walls that define the housing 101 can be perforated to facilitate collapsing/folding of housing 101.

Additionally, the smart packaging apparatus 100 can be used to recycle defective batteries by adding one or more fire-suppressant materials, such as CellblockEx material, which is a fire-suppressant silica sand, to the interior of the housing.

The inventors noticed that batteries inherently create a circular supply chain, as the batteries are made of valuable raw materials that should be collected and recycled at the end of the batteries life. Accordingly, the smart packaging apparatus 100 is reusable packaging and can, therefore, reduce both cost and waste. The smart packaging apparatus 100 can be used to deliver batteries for installation and replacement and can be used to retrieve batteries for return material authorizations (RMA) and end of life (EOL). The smart packaging apparatus 100 provides a robust packaging that may sometimes be necessary to manage damaged batteries. The smart packaging apparatus 100 provides high value packaging that can increase safety and decrease attrition.

While the foregoing is directed to embodiments of the present disclosure, other and further embodiments of the disclosure may be devised without departing from the basic scope thereof, and the scope thereof is determined by the claims that follow.

1. An apparatus for smart packaging and inventory control, comprising:
a housing comprising a lid configured to be opened and closed to allow a battery to be loaded and unloaded to and from the housing; and
a controller configured to monitor at least one of a battery state of health or a battery state of charge when the battery is disposed in the housing and display the battery state of health or the battery state of charge of the battery via an indicator on the housing.

2. The apparatus of claim 1, further comprising a temperature sensor operatively coupled to the controller and configured to provide a temperature of the battery or an interior of the housing to the controller.

3. The apparatus of claim 2, further comprising a Peltier cooler that is operatively coupled to the temperature sensor and the controller and configured to maintain the interior of the housing at a predetermined temperature.

4. The apparatus of claim 3, wherein the predetermined temperature is <25° C.

5. The apparatus of claim 1, further comprising a fire-suppressant material that is disposed in an interior of the housing.

6. The apparatus of claim 1, wherein the battery state or health is calculated as a ratio of a retained capacity of the battery to an original capacity of the battery.

7. The apparatus of claim 6, wherein the battery state or health is calculated using an Equation (1) that represents a capacity loss at time step t and temperature T, an Equation (2) that represents a capacity retention update, and an Equation (3) that represents a SOH update.

8. The apparatus of claim 7, wherein
$$Equation ( 1 ) is {Q}_{loss} ( T , t ) = A * exp ( - B * t ) \times ( exp ( - {E}_{a} / {R}_{g} ( \frac{1}{T} - \frac{1}{25 + 273} ) ) ;$$
$$Equation ( 2 ) is {Cap}_{retention} ( t ) = {Cap}_{retention} ( t - 1 ) - {Q}_{loss} ( T , t ) ;$$
$$and$$
$$Equation ( 3 ) is SOH ( t ) = \frac{{Cap}_{retention} ( t )}{{Cap}_{initial}} ,$$
wherein parameters A, B, E, and R are obtained using curve fitting of experimental data.

9. The apparatus of claim 1, wherein the experimental data comprises long-term storage test data at different temperatures with periodic charge/discharge to assess remaining capacity.

10. The apparatus of claim 1, wherein the controller is further configured to automatically report battery state of health and battery state of charge daily and report any errors upon an occurrence thereof.

11. The apparatus of claim 1, further comprising an auxiliary power supply that is operatively connected to the controller to provide power to the controller for communicating via at least one of a wired communication or a wireless communication.

12. The apparatus of claim 1, further comprising a 24V power supply and control area network (CAN) connection to turn on a battery management unit (BMU) connected to the battery periodically and read the battery state of charge, wherein the controller is further configured to recharge of the battery if the battery state of charge falls outside of an acceptable range.

13. The apparatus of claim 10, wherein the acceptable range is about 20%-30%).

14. The apparatus of claim 1, wherein the housing is collapsible/foldable to store and transport the apparatus back and forth to/from a factory.

15. The apparatus of claim 14, wherein one or more walls that define the housing are perforated to facilitate collapsing/folding of housing.
